(19) United States
(12) Patent Application Publication
(10) Pub. No.: US 2008/0007922 A1
(43) Pub. Date: Jan. 10, 2008

(54) Apparatus Casing and a Canopy

(75) Inventors: Ingemar Hallin, Lidingo (SE); Jan Blomberg, Stockholm (SE); Bjorn Flemsater, Lidingo (SE); Anders Bergqvist, Stockholm (SE)

Correspondence Address: PEARNE & GORDON LLP, 1801 EAST 9TH STREET, SUITE 1200, CLEVELAND, OH, 44114-3108, US

(73) Assignee: DOMETIC SWEDEN AB, Solna (SE)

(21) Appl. No.: 11/722,429

(22) PCT Filed: Dec. 21, 2005
(86) PCT No.: PCT/SE05/01992

§ 371 Date: Sep. 17, 2007

(30) Foreign Application Priority Data
Dec. 22, 2004 (SE) 0403125-8

(51) Int. Cl. H05K 5/06

(52) U.S. Cl. 361/724

(57) ABSTRACT

An apparatus casing (1) for a computer, which casing includes a number of walls which together define a chamber for accommodating computer components wherein at least a first wall (2) includes a number of through-penetrating contact openings (4, 9) which are disposed to enable the connection of external cables (6) having electric contacts (7) to corresponding connection contacts (5) disposed at said contact openings and connected to chamber-accommodating components. With the intention of lowering the airborne operational noise exiting from the box and counteracting the leakage of air into the casing, the casing is fitted with an openable canopy (11) that includes a generally hermetic wall (11′) and an edge surface which, when the canopy is closed, lies against the outside of the first wall (2) around the contact opening (4, 9), and a sealing cable transit means (20) through which the cables (6) are able to extend, wherein the canopy (11) the cable transit means (20) and the first wall (2) form a space for accommodating the cable contacts (7) said space being delimited generally hermetically from the surrounding atmosphere outside the chamber. The invention also relates to a canopy (11) for such an apparatus box.

### FIELD OF INVENTION

The present invention relates to a computer accommodating apparatus box or casing that includes a number of walls which together define a computer component accommodating chamber, wherein at least one first wall includes a number of through-penetrating electric contact openings which are disposed to permit electrical contacts of external cables to be connected to corresponding electric connection contacts disposed at the electric contact openings and coupled to chamber accommodated components.

The invention also relates to a canopy for fitting to a computer accommodating box.

### BACKGROUND OF THE INVENTION

In recent time disturbing noise has become a progressively increasing problem in the case of modern stationary personal computers and server computers. This operational noise can be experienced as tiring and irritating by the user and by persons in the vicinity of the computer. Even relatively low operational noise that can not be experienced directly as disturbing can constitute an ergonomic inconvenience and cause, for instance, stress or other more or less serious harm to the user and to other persons in the vicinity.

The operational noise of a stationary computer is caused mainly by movable components in the computer apparatus box. These movable parts are included on the one hand in components that are connected directly to the main functions of the computer, such as hard disks and diskette units, CD-units and DVD-units and on the other hand in fans provided for cooling the computer components. The noise is caused partly by vibrations that occur as a result of movement of the movable components, these vibrations may be transferred to the air present in the box and transported together with the air as airborne noise to the surrounding atmosphere, through ventilation openings and other openings in the apparatus box. The vibrations are also able to propagate to the external surroundings of the box through fixedly mounted parts of the computer, where the noise is transferred to the air in the surrounding atmosphere, the sound being referred to as structure-borne sound. In addition to the noise caused by the cooling fans, the air flows generated in the box also generate airborne noise and structure-borne noise as a result of friction against fixed parts in the apparatus box.

The performance of modern computers is often enhanced by providing, e.g., several hard disks, which generate operational noise and heat, and other components that generate a relatively large amount of heat. In order to prevent such computers from overheating it is necessary to utilize large airflows in the case of conventional fan-cooling systems, these large airflows also increasing operational noise. A very high degree of development work has been carried out with the intention of reducing the operational noise while achieving satisfactory cooling of computer components at the same time. For example there have been used fans that have low and variable speeds. However, there is generally a logical incongruity between the desire to use high performance components that require effective cooling and to maintain the operational noise at a low level. Consequently, it has been necessary to ignore the low noise requirement, particularly in the case of modern high performance stationary personal computers and servers.

The inventors of the present invention are aware that the configuration of the airflow paths within the apparatus box of the computer are of decisive significance in order to achieve satisfactory cooling of the components in the box with the aid of a limited airflow. This insight has resulted in an invention for which there has been filed a Swedish patent application by the same applicants on the same day as the instant application, this Swedish application having the title “An apparatus box for computers”.

### DESCRIPTION OF THE PRIOR ART

The apparatus box of earlier known stationary personal computers and server computers includes a number of openings. These openings are partly ventilation openings for delivering and removing cooling air, and partly electric contact openings which accommodate the electric contacts used to connect external cables, such as net cables and cables that power the screen, keyboard, loud speakers, printer, network, etc. All of these openings often allow air to exit from the apparatus box and therewith contribute towards allowing the airborne operational noise to exit to the surroundings. These electric contact openings thus constitute a serious problem with regard to achieving truly silent computers.

Another problem created by the electric contact openings is that they allow air to pass into to the box from the surroundings. This leakage of air into to the apparatus box disturbs the intended air-flow-paths from the ventilation inlet to the ventilation outlet and therewith reduce the efficacy of the air cooling system, therewith requiring large total air flows with the subsequent increase in operational noise. This problem is exacerbated often by the user himself/herself because he/she is often able to re-construct the computer and therewith change the number of electrical connection contacts. The computer manufacturer is thus unable to determine the leakage flows that can occur when he/she dimensions the cooling flow and choose appropriate positioning of the computer components with regard to cooling of the components. The leakage flows that occur through the connection openings thus constitute a very serious obstacle in the ability of creating an optimal air flow within the apparatus box. With the intention of reducing operational sound that reaches the surroundings, endeavors has been made to this end with noise insulated boxes in which typical computers can be placed. This noise insulated box will often have noise insulated walls, a closable front entrance through which the computer is inserted and which allows the presence of diskette units, CD-units and DVD-units and some type of cable transit of the external cables and a cooling fans. These noise insulated boxes, however, have not gained particular success commercially. Firstly, the boxes are relatively large, clumsy and heavy, and secondly they significantly laden the user with additional costs. Moreover, they fail completely to solve the problems associated with the leakage of air in through the connection openings present in the apparatus box.

### SUMMARY OF THE INVENTION

Accordingly, one object of the present invention is to provide an apparatus casing for a computer with which the airborne noise that exits to the surroundings can be considerably reduced in a simple, less cumbersome, aesthetically attractive and inexpensive fashion.

Another object is to provide such a casing that enables the air-flow paths within the casing to be optimized by reducing the ability of air flows to leak into the casing.

A further object of the present invention is to provide such an apparatus casing which will allow greater selectivity and flexibility with regard to the number of computer connections and external cables, and also their design and placement.

Still another object is to provide such an apparatus casing with the aid of a simple auxiliary device in the torn of a canopy that can be fitted to commercially available computers.

These and other objects are achieved with an apparatus casing of the kind defined in the first paragraph of this description which casing has the particular features set forth in the characterizing clause of the accompanying claim 1.

The arrangement of an air tight canopy that includes a sealing cable transit means around the connection openings of the casing prevents air from exiting and entering through the connection openings and also the connection contacts disposed in said openings. This prevents airborne operational noise from exiting through said openings and said contacts to the surroundings in a very simple, space-saving and inexpensive fashion, therewith reducing the noise that reaches the surroundings. In addition, leakage flows through the contact openings and the connection contacts into the apparatus casing are prevented, thereby enabling the desired airflow paths to be accurately controlled from inlet to outlet. Moreover, there is provided greater selectivity with regard to the configuration and design of the canopy, which can be made aesthetically attractive and caused to conform to the remaining design of the computer. A canopy constructed in accordance with the invention also enables the user to add and remove connection contacts and external cables himself without the risk of influencing the operational sound of the computer or the intended interior air-flow paths.

The cable transit arrangement will conveniently comprise a resilient deformable first element that can be caused to sealingly embrace a large part of the cross-sectional area of the external cables. Such a resilient element will provide a good sealing effect regardless of the cross-sectional geometry of the cables, therewith allowing selective use of many different types of cable.

The first element will conveniently co-act with a second element, said first and second elements being seated on a respective side of the canopy and a wall of the apparatus box. When fitted, the cables are embraced sealingly by the clamping action between said two elements. This solution enables the cables to be readily released when the canopy is opened or removed. A new cable can be fitted and an existing cable removed very readily, owing to the fact that the cable and its associated electrical contact need not be threaded through the cable transit means. A still better seal around the cross-sectional geometry of the cables is achieved when the second element is also resiliently deformable, therewith enabling a greater variation in the cross-sectional geometry of the cables while retaining a good sealing effect. The space enclosed by the canopy can be further enhanced by providing a sealing strip between the canopy and the box wall with which it abuts. The sealing strip will be conveniently fastened to either the box or the wall. The canopy may be hinged to the apparatus box so as to enable the canopy to be opened and closed. However, the canopy may be removably fastened to the box with the aid of screws, snap fasteners, hooks or corresponding devices. This will afford greater freedom of movement and better access adjacent and around the contact openings of the box, for instance when cables shall be connected and disconnected and when connection contacts shall be fitted and removed.

Further objects of the invention and benefits afforded thereby will be evident from the following description and the accompanying claims.

The invention also relates to a canopy for connection to an apparatus casing, according to claim 8.

### BRIEF DESCRIPTION OF THE DRAWINGS

Exemplifying embodiments of the present invention will now be described with reference to the accompanying drawings, in which

FIG. 1 is a schematic perspective view of one exemplifying embodiment of the apparatus casing and the canopy according to the present invention;

FIG. 2 is a sectional view of a lower part of the embodiment shown in FIG. 1, taken on the line II-II in said figure; and

FIG. 3 is a sectional view taken on the line III-III in FIG. 2.

### DETAILED DESCRIPTION OF EXEMPLIFYING EMBODIMENTS

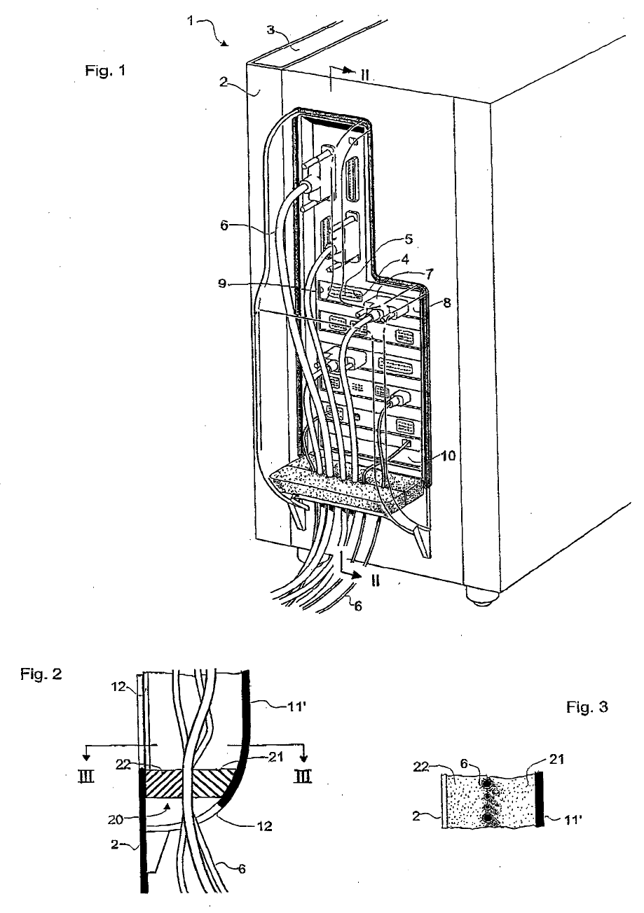

FIGS. 1-3 illustrate an embodiment of an apparatus casing or box 1 according to the present invention. The box comprises a number of walls, including a rear wall 2. The box walls define an inner chamber that is generally delimited hermetically from the surroundings, with the exception of via an air inlet 3 and an air outlet (not shown), said air being driven with the aid of fans disposed within the box so as to cool the computer components mounted in the box. The rear wall 2 of the box includes a number of electric contact openings 4. The contact openings are typically provided either directly in a metal sheet? that forms the major part of the rear wall 2 or in a smaller plate 8 which is fastened to an electronic card connected, for instance, to the motherboard of the computer. The plate 8 covers large openings 9 disposed in the rear wall 2 and which at those places where no electronic card is present are covered by firmly screwed covering plates 10. The contact openings accommodate connection contacts 5 for connecting external cables 6 with the aid of cable contacts 7. By external cable 6 is meant such cables, conductors and leads that are connected the apparatus box and units positioned externally of the box for the transmission of electric power and electrical or optical signals for instance. Both the contact openings 4 and the connection contacts 5 and the large openings 9, with or without plates 8 or cover plates 10, permit the passage of air into and out of the box chamber to a greater or lesser extent.

According to the invention, a canopy 11 is disposed on the rear wall 2. The canopy 11 includes an air tight wall 11′ comprised of a transparent polymer material. The wall 11′ of the canopy 11 has an edge surface with which it abuts the rear wall 2 of the box 1. A sealing strip 12 comprised of an elastic sealing material is fastened to the edge surface of the box 11 so as to seal against the rear wall 2 of said box. An interruption or discontinuity is located in the edge surface at the lower part of the canopy 11 so that said lower part will present an opening 12 when the canopy 11 abuts the rear wall 2 of the box. A cable transit means 20 is provided immediately above the opening in the canopy 11. The cable transit means 20 includes a first element 21 comprised of an elastically deformable material fastened to the canopy wall 11′, and a second element 22 comprised of a similar elastically deformable material that is fastened to the rear wall of the box immediately beneath the lowermost contact opening in the rear box wall 2. The first element 21 and the second element 22 have the form of horizontally extending blocks? which lie in abutment with one another under a given degree of bias when the canopy is mounted in position and closed.

The canopy is also fastened to the rear wall of the box with the aid of fasteners (not shown) in the form of snap books which are mounted on the rear wall and which co-act with box-mounted shoulders. It will be understood, however, that the canopy can be fastened to the box wall in many different ways, such as with the aid of screws, sprung hinges, etc. for instance.

As illustrated in the drawings, when the canopy is fitted, the edge surface thereof together with the second element 22 of the cable transit 20 will extend around all openings in the rear wall 2 of the box. Thus, the canopy with the cable transit means 20 and the sealing strip 12 will form together with the rear wall of the box a space which is generally delimited from the surrounding atmosphere outside the box in an air tight fashion.

When wishing to connect one or more external cables 6 to the connection contacts 5 in the rear wall 2, the canopy 11 is loosened from the rear wall 2. The first element 21 of the cable transit means 20 is therewith removed from the second element 22 so as to provide free access to the connection contacts and sufficient space to connect the electric contacts 7 of the external cables 6 to respective electrical connection contacts 5. Subsequent to having connected all external cables 6 it is ensured that the cables lie side-by-side along the second element 22 of the cable transit means fastened to the rear wall. The canopy 11 is then re-fitted. The cables are then able to pass freely out through the bottom opening 12 of the canopy with the first element 21 and the second element 22 of the cable transit means 20, each embracing its respective cross-sectional path of the cables, as will best be seen from FIG. 3.

Because the first element 21 and the second element 22 are in abutment with a given degree of bias it is ensured that a highly effective seal is obtained even when the cables 6 have highly varying cross-sectional dimensions and geometries.

Thus, there is obtained in this way with the aid of simple, readily used, inexpensive, and aesthetically attractive means that require but a small amount of space an extremely effective seal that prevents both air and airborne noise from exiting from the apparatus box and also prevents from the ingress of surrounding air into the box through any of the connection openings provided in the rear wall 2 of the box.

Although the invention has been described with the aid of exemplifying embodiments it will be understood that the invention is not restricted to the exemplifying embodiment and that variations can be made within the scope of the accompanying claims.

1. An apparatus casing (1) for a computer, which casing includes
a number of walls which together define a chamber for accommodating computer components
wherein at least a first wall (2) includes a number of through penetrating contact openings (4, 9) which are disposed to enable the connection of external cables (6) having contacts (7) to corresponding electric connection contacts (5) disposed at said contact openings and connected to components in the chamber characterized by
an openable canopy (11) that includes a generally hermetical wall (11′) and an edge surface which, when the canopy is closed, lies against the outside of the first wall (2) around the contact opening (4, 9), and by
a sealing cable transit means (20) through which the cables (6) are able to extend, wherein
the canopy (11), the cable transit means (20) and the first wall (2) form a space for accommodating the cable contacts (7) said space being delimited generally hermetically from the surrounding atmosphere outside the chamber.

2. An apparatus casing according to claim 1, wherein the cable transit means (20) includes an elastically deformable first element (21).

3. An apparatus casing according to claim 2, wherein the cable transit means (20) includes a second element (22) which co-acts with the first element (21), wherein the first and the second elements are mutually separated as the canopy (11) is opened so as to allow insertion of external cables (6) with cable contacts (7) and, when the canopy is closed, abut one another and sealingly surround the cross-sectional geometry of the inserted cables.

4. An apparatus casing according to claim 3, wherein the first element (21) and the second element (22) of the cable transit means are each disposed on a respective part of the canopy (11) and on the first wall (2).

5. An apparatus casing according to any one of claims 3-4, wherein the second element (22) is elastically deformable.

6. An apparatus casing according to any one of claims 1-5, wherein a sealing strip (12) is disposed between the edge surface of the canopy (11) and the first wall (2).

7. An apparatus casing according to any one of claims 1-6, wherein the canopy (11) can is removable from the apparatus casing (1).

8. A canopy which is intended to be fitted to an apparatus casing (1) for a computer, which casing includes a number of walls that together define a computer component accommodating chamber, wherein at least a first wall (2) includes a number of through-penetrating contact openings (4, 9) which are adapted to enable external cables (6) having contacts (7) to be connected to corresponding contacts (5) disposed in the contact openings (4, 5) and connected to components present in the chamber, characterized in that
the canopy (11) includes a generally hermetically sealed wall (11′); an edge surface which is formed for abutment with the first wall (2) around the contact openings (4, 9); and
at least one first cable transit element (21) which is formed to co-act with a second cable transit element (22) such as to sealingly embrace the cross-sectional geometry of the external cables (6) that extend between the two cable transit elements so that the sealing wall (11′) of the canopy, the two cable transit elements (21, 22) and the first wall (2) define a space for receiving the cable contacts (7) when the canopy is fitted to the apparatus box, the space being delimited generally hermetically from the surrounding atmosphere external of the chamber.
